(19) United States
(12) Patent Application Publication
(10) Pub. No.: US 2005/0092599 A1
(43) Pub. Date: May 5, 2005

(54) Apparatus and process for high rate deposition of rutile titanium dioxide

(76) Inventors: Norm Boling, SantaRosa, CA (US); Eric Krisl, Santa Rosa, CA (US); Mark George, Santa Rosa, CA (US); Miles Rains, Santa Rosa, CA (US); H. Robert Gray, Sebastopol, CA (US)

Correspondence Address: DUANE MORRIS LLP, Suite 700, 1667 K Street, N.W., Washington, DC, 20006, US

(21) Appl. No.: 10/959,504

(22) Filed: Oct. 7, 2004

Related U.S. Application Data
(60) Provisional application No. 60/508,871, filed on Oct. 7, 2003.
(60) Provisional application No. 60/508,877, filed on Oct. 7, 2003.
(60) Provisional application No. 60/512,002, filed on Oct. 17, 2003.

(51) Int. Cl. C23C 14/32

(52) U.S. Cl. 204/192.22; 204/298.25; 204/298.23; 204/298.28

(57) ABSTRACT

An apparatus and process for forming thin films of titanium dioxide in the rutile phase by reactive sputter deposition. In one aspect, a sputtering target and auxiliary plasma generator are positioned in a coating station in a sputtering chamber so that the titanium deposited on a substrate passing through the coating chamber is oxidized by exposure to the auxiliary plasma generated by the plasma generator commingled with the sputter plasma. The plasma may include monatomic oxygen to assist in the formation of rutile titanium dioxide. The target, or a pair of targets may also be operated from pulsed d.c. or a.c. power supplies.

### CLAIM OF PRIORITY

The present application claims the benefit of the filing date of U.S. Patent Application No. 60/508,871 filed Oct. 7, 2003, U.S. Patent Application No. 60/508,877 filed Oct. 7, 2003, and U.S. Patent Application No. 60/512,002 filed Oct. 17, 2003. Each of the above-identified applications is incorporated herein by reference.

### BACKGROUND OF THE INVENTION

Multilayer optical coatings typically consist of alternating layers of materials having high and low indices of refraction. In general it is advantageous to form a multilayer coating from high and low index material where the ratio of the high index to the low index is as large as possible. A multilayer coating formed from materials having a larger index ratio may be formed with fewer layers to achieve the same optical performance as a coating formed from materials having a lower index ratio. Additionally, a multilayer coating having superior optical performance can be achieved using an equal, or fewer, number of layers by replacing one high index material with another high index material having a larger index. The economics of an optical coating process will be determined by the number of layers required to provide a desired optical result, the rate at which such layers can be deposited, and the surface area over which those deposition rates can be achieved. Fewer layers, and therefore a thinner coating, will also be beneficial due to such characteristics as lower stress and/or scatter compared to thicker coatings.

Metal oxides have found wide use in optical coating applications because they are durable and generally have good transmission in the visible spectrum. Titanium dioxide (TiO₂) has long been recognized as a potentially valuable high index material for optical coating applications because it is durable, visually transparent, and has a higher index than any other suitable metal oxide. However, the use of titanium dioxide has been severely limited due to several manufacturing difficulties. The foremost difficulty results from the fact that titanium dioxide has three naturally occurring crystalline phases: rutile, anatase, and brookite. Under certain conditions it can also be deposited in a non-crystalline, amorphous form. Of these various phases, the rutile phase has the highest, and therefore most desirable, refractive index. Rutile titanium dioxide is birefringent, with an average index of 2.75 at 550 nm and is the most thermodynamically stable phase. A further problem exists in that even when rutile titanium dioxide is deposited, it is often absorbing due to difficulties in oxidizing the film unless the deposition rate is so slow as to be economically impractical.

Although the rutile phase is the most thermodynamically stable, it requires very high energies to form rutile titanium dioxide directly during growth of the thin film. The energy required can be supplied by the deposition process, by heating of the substrate, or both. The phase diagram of deposited titanium dioxide as a function of substrate temperature and deposition process has been published and is shown in FIG. 1. With reference to FIG. 1, it is apparent that low energy deposition techniques require an impractically high substrate temperatures to achieve the deposition of rutile titanium dioxide. Nearly all prior art methods for deposition of thin films of titanium dioxide yield either amorphous, anatase, or a mix of anatase and rutile films. These results are less desirable than obtaining titanium dioxide in substantially all rutile phase because the refractive index of the anatase phase is substantially lower (n=2.45 @ 550 nm) than that of the rutile phase. Heating of the anatase or amorphous phases to temperatures above approximately 500° C. causes a phase change to rutile, however the phase change is often accompanied by crystal growth that results in undesirable scatter properties in the film. Deposition of mixed rutile and anatase films is particularly undesirable in that the index of such mixtures is difficult to predict and control, leading to poor optical performance in the coating.

Previous attempts to deposit rutile titanium dioxide have utilized techniques such as heating the substrates to high temperatures, use of ion beam sputtering, or RF sputtering. Heating the substrates to the temperature required to form rutile titanium dioxide is often impractical in manufacturing, and in many cases the heat will physically damage the substrates. RF sputtering and ion beam sputtering allow the formation of films composed substantially of rutile titanium dioxide at temperatures less than 200° C., however, the deposition rate is slow and thus economically impractical and, in the case of ion beam sputtering, the area coated is small and thus economically impractical.

For these reasons use of titanium dioxide in optical coatings has been mostly limited to deposition of the lower index anatase phase and applications where the temperature at which the film must perform is low.

The present invention in one aspect provides for the deposition of thin films of titanium dioxide that are substantially composed of rutile titanium dioxide on one or more substrates at higher rates, lower absorption, and lower temperatures than have been heretofore possible. The coating process and system may provides for the deposition of titanium dioxide in successive monolayers from a target operating primarily in the metallic mode. The term “monolayer” as used herein means a layer of material that is no more than one atom in thickness. Depositing a monolayer does not mean that the entire surface on which the monolayer is deposited are covered by atoms of the deposited material, but only that the material deposited is no more than one atom in thickness. Each newly deposited monolayer is fully oxidized under conditions resulting in the formation of rutile titanium dioxide before the next monolayer is deposited over the previous layer. The deposition process is performed at moderate temperatures and at rates that are significantly faster than those of other coating techniques.

Accordingly, it is an object of the present invention to obviate many of the above problems in the prior art and to provide a novel apparatus and process for high rate deposition of thin films of rutile titanium dioxide. These and many other objects and advantages of the present invention will be readily apparent to one skilled in the art to which the invention pertains from a perusal of the claims, the appended drawings, and the following detailed description of various embodiments.

### BRIEF DESCRIPTION OF THE DRAWINGS

FIG. 1 is a phase diagram for thin films of vacuum deposited titanium dioxide taken from P. Lobl, Thin Solid Films 251, 72-79 (1994).

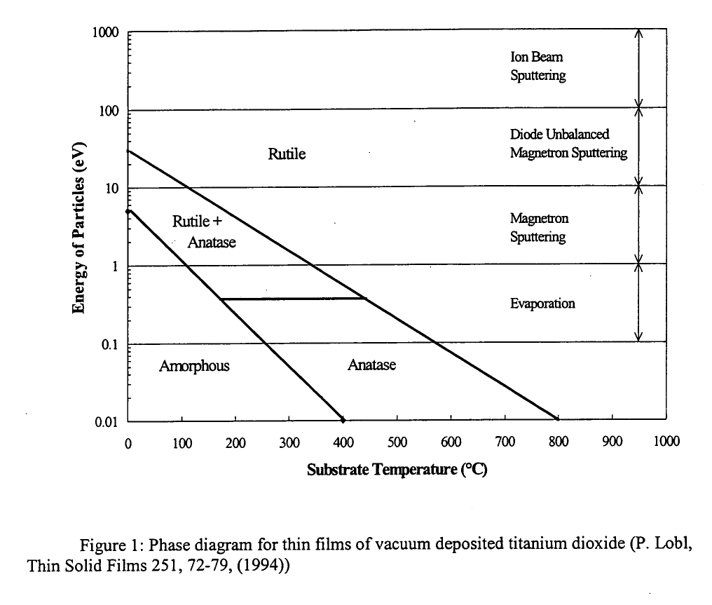

FIG. 2 is a schematic representation of a coating system according to one aspect of the present invention.

FIG. 3 is an illustration of the measured compared to theoretical transmittance vs. wavelength of a thin film formed according to one aspect of the present invention.

FIG. 4 is an illustration of the measured compared to theoretical transmittance vs. wavelength of a thin film formed according to another aspect of the present invention.

### DESCRIPTION

With reference to the drawings, like numerals represent like components throughout the several drawings.

The present invention is directed to systems and processes for forming thin films of titanium dioxide formed in substantially all rutile phase. In one aspect, the invention is directed to reactive sputter coating systems and processes for forming thin films of rutile titanium dioxide. The system includes a sputtering chamber having one or more coating stations and a means for mounting and moving one or more substrates through the coating stations. The system and process may include a batch coating process wherein the mounting and moving means comprises a rotatable drum, table, disk, or other transporting device of suitable geometry. A reactive coating system and process suitable for forming thin films of rutile titanium dioxide is disclosed in U.S. Pat. No. 5,849,162 to Bartolomei et.al., the content of which is incorporated herein by reference.

The sputtering chamber includes one or more coating stations. At least one sputtering target is positioned in the coating station. In one aspect, the target comprises a magnetron sputtering device. The target is operated at a power sufficient to create a reactive atmosphere in the coating station and to plasma sputter titanium or an oxide of titanium onto the substrates that are moved through the coating station on the mounting and moving means.

A plasma generating device is also positioned in the coating station adjacent the target. In one aspect, the plasma generating device comprises a microwave generator. The plasma generator is operated at a power level for generating a plasma in the coating station that interdiffuses with the plasma generated by the target to increase the area, density, and reactivity of the reactive atmosphere in the coating station.

In one aspect, the present invention provides direct deposition of rutile titanium dioxide films at relatively low substrate temperatures by providing energy to the growing film in several forms. The energy is provided by a combination of the magnetron target plasma and the plasma generated by the plasma generating device. The present invention forms thin films of rutile titanium dioxide films that are essentially stochiometric as formed. This is accomplished by introduction of oxygen into the adjacent plasma, and by relatively rapid translation of the substrates into and out of close proximity to the target surface in the coating station. On each successive pass by the target a monolayer of titanium is deposited and then completely oxidized at energies sufficient to form rutile titanium dioxide. This oxidation of the film is accomplished before the substrate passes by the target once again and acquires a fresh layer of titanium metal.

In one embodiment, the adjacent plasma is of sufficient intensity to provide significant quantities of monatomic oxygen. Exposing the deposited titanium to monatomic oxygen permits the complete oxidation of the titanium being deposited without having to operate the target(s) in a poisoned mode and suffer the resulting large decrease in deposition rate. Previous attempts to deposit titanium dioxide at high rates suffered from this inability to completely oxidize the film, with the result that the deposited films were unacceptably absorbing. Without the adjacent plasma, the oxygen available to react with the freshly deposited titanium metal on the substrate surface is mainly diatomic in nature. To form titanium dioxide by reacting diatomic oxygen and titanium requires a high activation energy. Due to the high activation energy, the titanium is not completely oxidized.

In one aspect of the present invention, the plasma generating device provides a plasma containing monatomic oxygen which reacts much more easily with the titanium metal. Thus it is possible to completely oxidize the film and obviate the disadvantages of forming absorbing films.

The provision of monatomic oxygen to the growing film is important for the rapid and complete oxidation of the titanium atoms on the substrate surface, but it also has another benefit because it provides more energy to the growing film. This increased energy is provided by the heat of reaction of the monatomic oxygen with the titanium atoms, as compared to the lower heat of reaction that would be provided by reaction of the titanium atom with diatomic, molecular oxygen. Reaction of a diatomic oxygen molecule with a titanium atom requires at least formally that the oxygen molecule first be split into monatomic oxygen. This is a highly endothermic reaction, and the necessary energy for splitting the oxygen molecule is subtracted from the energy released by reaction of the oxygen atom and the titanium atom, giving a lower net energy release for the reaction of diatomic oxygen with titanium as compared to the reaction of monatomic oxygen atoms with titanium.

It is often desirable to operate the titanium target(s) in a substantially metallic mode so that material sputtered from the target consists primarily of titanium atoms. The oxygen is introduced into the adjacent plasma to provide activated oxygen species that fully oxidize the deposited titanium atoms. The energy released on oxidation of the titanium atoms contributes to the energy necessary to from the titanium dioxide in the rutile phase. Methods for control of the target oxidation state while maintaining a high sputtering rate are disclosed in U.S. Pat. No. 5,849,162.

In many situations it may be desirable to provide at least one additional coating station equipped with targets that permit sputtering of materials other than titanium. By alternating use of the coating stations, the present invention provides for the formation of multilayer coatings in which at least one of the layers is composed of substantially rutile titanium dioxide. It may also be desirable to provide more than one coating station capable of sputtering titanium in order to increase the overall deposition rate of rutile titanium dioxide on the substrates.

In one aspect of the present invention, balanced magnetrons are operated from an a.c. power supply. The use of an a.c. power supply aids in the formation of rutile titanium dioxide. In an a.c. sputtering system the power switches back and forth between the two targets, with each target alternately acting as the cathode and then the anode in the course of one cycle of power. At the frequencies used, the plasma decays significantly when the power is switched between the two targets (a time on the order of a few tens of microseconds), meaning that the plasma must be restruck over the target that is operating as the cathode. This higher energy needed to restrike the plasma over the target results in a higher electron temperature for the sputtering plasma, resulting in a higher sheath voltage around the substrate as it passes through the plasma. This in turn causes a higher energy ion bombardment of the substrate. This higher energy bombardment facilitates both the oxidation of the titanium atoms deposited on the substrate and the formation of the rutile titanium dioxide.

Other a.c. powered configurations and other power supplies may also be used to provide the higher electron temperature in the plasma to aid the formation of rutile titanium dioxide. Unbalanced a.c. magnetrons, as well as a pulsed d.c. magnetron, also require restriking of the plasma over the target and thus provide the benefit of higher electron temperatures in the plasma. The a.c. configurations also have the advantage that each target functions alternately as the anode and then the cathode so that the targets are kept clean of oxide buildup on their surface and the anode is never lost. In pulsed d.c. systems, only one target is present and it is always the cathode, making it easier for wandering anode problems to occur in the chamber. Other power supplies and target configurations may be used, although with some loss of rate and film quality.

It will often be advantageous, in order to provide coating of many substrates within one operation, to provide a system with relatively long sputtering targets, an elongated plasma generator, and a substrate holder capable of holding a large number of substrates.

It may also be desirable to provide a method for secondary movement of the substrate(s) with respect to the transporting device to improve uniformity of deposition on the substrate(s). For example, the substrate could be rotated about its center point, translated across some aspect of the transporting device, or some combination of these without departing from the current invention. U.S. Pat. No. 6,485,646 discloses a coating system wherein a secondary movement is provided to the substrates to improve uniformity of the coating on the substrates and among an array of substrates.

The present invention provides a system and process for forming thin films of rutile titanium dioxide with low absorption, at high rates, and low temperatures, the combination of which has heretofore been unrealized using reactive sputtering systems. Unlike ion beam sputtering, this process can be carried out on a relatively large throughput of substrates. The combination of high deposition rates and multiple substrates makes the current invention of great economic advantage in the manufacture of articles with rutile titanium dioxide coatings, such as multilayer optical coatings. It also makes titanium dioxide a usable coating material in applications where it would previously have not been feasible.

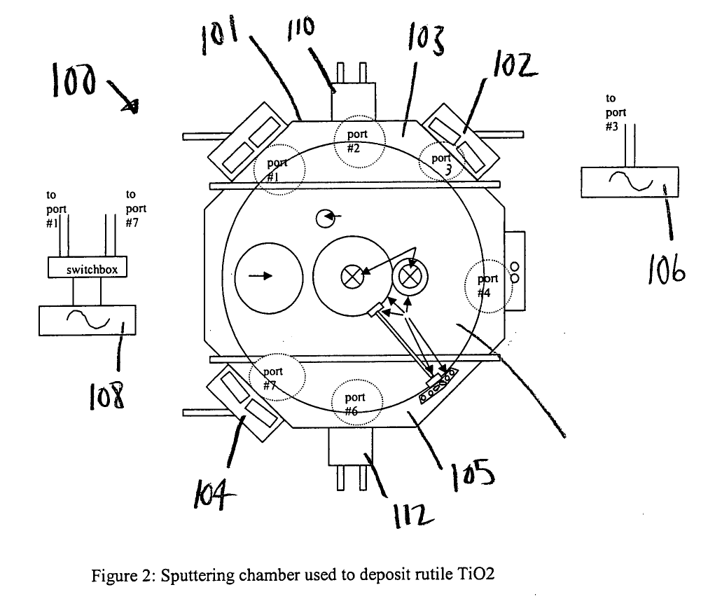

FIG. 2 is a schematic illustration of a reactive coating system according to one aspect of the present invention. With reference to FIG. 2, the coating system 100 includes a chamber 101 having two coating stations 103 and 105. The titanium cathode pair 102 is positioned in coating station 103 and is powered from the a.c. power supply 106. The titanium cathode pair 104 is positioned in coating station 105 and is powered by a.c. power supply 108. The a.c. power supplies may be operated at any suitable frequency, but generally between 10 kHz and 100 kHz. The plasma generating device 110 is positioned in coating station 103 adjacent the cathode pair 102. The plasma generating device 112 is positioned in coating station 105 adjacent the cathode pair 104. The system may be operated by operating the targets and plasma generating devices in one coating station or in both coating stations simultaneously. The drum 114 provides the means for mounting and moving one or more substrates through the coating stations.

Oxygen is inlet into the chamber at the same port as the plasma generating devices 110, 112. This configuration may also provide for the secondary rotation of the substrates, which rotation rate is independent of the drum rotation rate.

### EXAMPLE

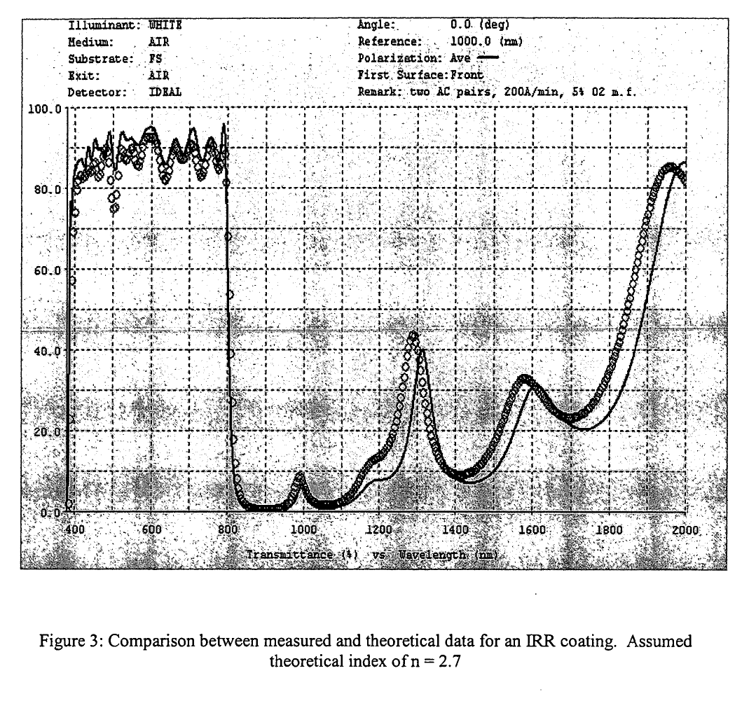

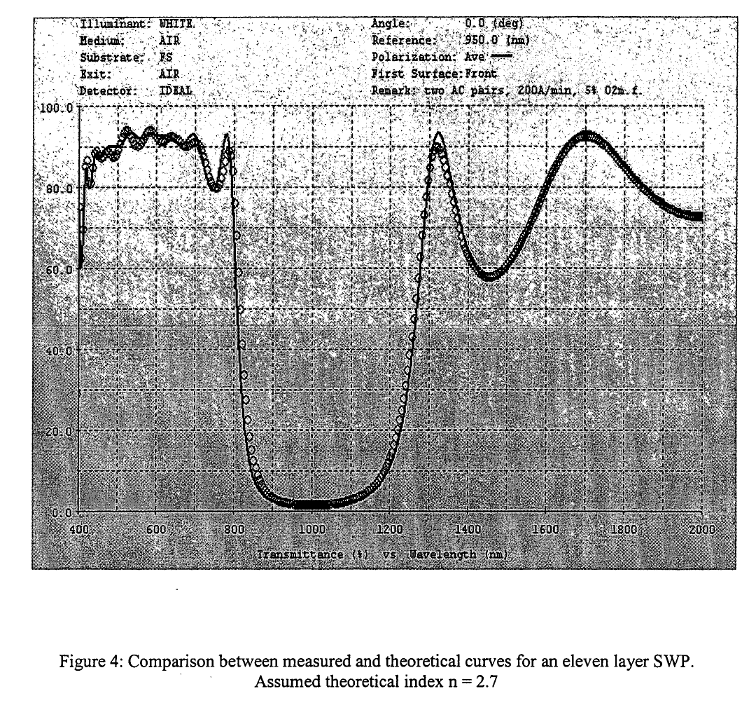

A coating system configured as shown in FIG. 2 was used to form (i) an IRR (Infrared Red Reflector) coating and (ii) an eleven layer SWP (short wave pass) coating. The a.c. power supplies 106 and 108 were operated at 65 kHz and 40 kHz respectively. The measured results for these two coatings, as compared to theoretical predictions is shown in FIGS. 3 and 4 respectively. The theoretical curves were calculated assuming the use of rutile titanium dioxide with an index of 2.7 @ 550 nm. The measured results show coatings having rutile titanium dioxide with low absorption were formed using the system and process shown in FIG. 2. Measured rates show that the titanium dioxide was deposited at a rate of 10 nm/min using one a.c. cathode pair, and at as rate of 20 nm/min if both titanium cathode pairs were operated simultaneously. The coatings exhibited an absorption with a k value of less than 10×10⁻⁴ after baking the substrates at about 500° C. for about one hour.

While preferred embodiments of the present invention have been described, it is to be understood that the embodiments described are illustrative only and that the scope of the invention is to be defined solely by the appended claims when accorded a full range of equivalence, many variations and modifications naturally occurring to those of skill in the art from a perusal hereof.

1. In a sputter coating system comprising:
a vacuum chamber having a coating station;
substrate mounting and moving means adapted for passing one or more substrates to be coated through said coating station;
means for introducing a oxygen into said chamber;
a titanium target operating at a predetermined power level sufficient to create a reactive atmosphere in said coating station and to plasma sputter titanium from said target onto substrates when passed through said coating station by said mounting and moving means; and
a plasma generator for operating at a predetermined power level for increasing the area, density, and reactivity of the reactive atmosphere in said coating station,
a method of forming a thin film of rutile titanium dioxide comprising the steps of operating the target and plasma generator at power levels at which substantially all of the titanium sputtered onto the substrates is oxidized to form titanium dioxide in the rutile phase.

2. The method of claim 1 further comprising the step of moving the substrates through the coating station at a speed sufficient for depositing and oxidizing a monolayer of titanium in a single pass through the coating station.

3. The method of claim 1 wherein the target is a magnetron sputtering target.

4. The method of claim 1 wherein the system comprises a pair of magnetron sputtering targets, said method further comprising the step of operating the targets from an a.c. power supply so that each target alternately forms the cathode and the anode during one cycle of power.

5. the method of claim 1 wherein the plasma generator includes a microwave generator.

6. The method of claim 1 wherein the reactive atmosphere includes monatomic oxygen.

7. The method of claim 1 further comprising the step of operating the plasma generator at a power level such that the reactive atmosphere collectively produced by the plasma generator and the target oxidizes substantially all of the deposited titanium without poisoning the target.

8. A process for forming a thin film on a substrate comprising the steps of depositing titanium on the substrate and exposing the deposited titanium to oxygen, the improvement wherein the titanium is deposited in a monolayer and exposed to oxygen to oxidize substantially all of the deposited titanium forming a film consisting essentially of rutile titanium dioxide.

9. The process of claim 8 wherein the steps of depositing and exposing the monolayer of titanium are repeated to obtain a predetermined thickness of a thin film consisting essentially of rutile titanium dioxide.

10. The process of claim 8 wherein the monolayer of titanium is exposed to monatomic oxygen.

11. The process of claim 8 wherein the monolayer of titanium is sputtered onto the substrate.

12. The process of claim 11 wherein the monolayer of titanium is exposed to monatomic oxygen.

13. The process of claim 8 wherein the temperature of the substrate is less than 200° C.

14. The process of claim 8 wherein the thin film is exposed to a temperature greater than about 400° C. for a predetermined period of time.

15. The process of claim 14 wherein the thin film is exposed to a temperature of about 500° C. for a predetermined period of time.

16. A process for forming a thin film on a substrate comprising the steps of sputter depositing titanium on the substrate and oxidizing the titanium to form titanium dioxide, wherein sufficient energy is provided to the titanium and oxygen to form substantially all of the titanium dioxide in the rutile phase, the improvement comprising the step of commingling an auxiliary plasma with the sputtering plasma and providing at least a portion of the energy by exposing the deposited titanium to the commingled plasma.

17. The process of claim 16 wherein the heat of reaction between monatomic oxygen and titanium comprises a portion of the energy provided to the titanium and oxygen.

18. The process of claim 16 wherein the temperature of the substrate is less than 200° C.

19. The process of claim 16 wherein the target is operated from an a.c. power supply.

20. The process of claim 19 wherein a pair of targets are operated from an a.c. power supply.

21. A process for forming a thin film consisting essentially of rutile titanium dioxide comprising the steps of:
moving one or more substrates past a sputtering target;
sputter depositing a monolayer of titanium on the substrates during a single pass of the substrates past the target; and
oxidizing substantially all of the deposited titanium to form titanium dioxide in the rutile phase.

22. The process of claim 21 wherein the step of sputter depositing comprises operating the target from an a.c. power source.

23. The process of claim 21 wherein the step of oxidizing comprises exposing the deposited titanium to monatomic oxygen.

24. In a process for forming a thin film of Titanium dioxide on a substrate by sputter depositing titanium on the substrate and oxidizing the deposited titanium to form titanium dioxide, a method of providing sufficient energy to the film to form substantially all of the titanium dioxide in the rutile phase comprising the step of exposing the deposited titanium to a plasma containing monatomic oxygen.

25. A sputter coating system comprising:
a vacuum chamber having a coating station;
substrate mounting and moving means adapted for passing one or more substrates to be coated through said coating station;
means for introducing oxygen into said chamber;
a titanium target operating at a predetermined power level sufficient to create a reactive atmosphere in said coating station and to plasma sputter titanium from said target onto substrates when passed through said coating station by said mounting and moving means; and
a plasma generator for operating at a predetermined power level for increasing the area, density, and reactivity of the reactive atmosphere in said coating station,
wherein the target and plasma generator are operated at power levels at which substantially all of the titanium sputtered onto the substrates is oxidized to form titanium dioxide in the rutile phase.

26. The system of claim 25 wherein the plasma generator is operated at a power level such that the reactive atmosphere collectively produced by the plasma generator and the target oxidizes substantially all of the deposited titanium without poisoning the target.

27. The system of claim 25 wherein said target includes a magnetron sputtering target.

28. The system of claim 25 comprising a second titanium target operating at a predetermined power level sufficient to create a reactive atmosphere in said coating station and to plasma sputter titanium from said target onto substrates when passed through said coating station by said mounting and moving means;

29. The system of claim 28 wherein the targets are operated by an a.c. power supply so that each target alternately forms the cathode and the anode during one cycle of power.

30. The system of claim 25 wherein the plasma generator includes a microwave generator.

31. The system of claim 25 wherein the mounting and moving means includes a generally cylindrical drum rotatable about its axis.

32. The system of claim 31 wherein the mounting and moving means includes means for moving the substrates mounted thereon relative to the surface of the drum.

33. The system of claim 25 wherein the mounting and moving means includes a disc rotatable about its axis.

34. The system of claim 33 wherein the mounting and moving means includes means for moving the substrates mounted thereon relative to the surface of the disc.

35. The system of claim 25 further comprising a second coating station, a target positioned at said second coating station, and a plasma generator positioned at said second coating station.

36. The system of claim 25 further comprising a second target positioned at said coating station.

37. A system for forming a thin film of titanium dioxide comprising:
a sputtering chamber having a coating station;
means for mounting and moving one or more substrates through said coating station;
means for introducing oxygen into said coating station;
a titanium sputtering target positioned in said coating station, said sputtering target generating a sputter plasma for sputtering titanium onto substrates positioned in said coating station adjacent the sputtering surface of said target;
a plasma generating device positioned in said coating station, said plasma generating device generating a plasma containing monatomic oxygen that commingles with the sputtering plasma generated by said target,
wherein said mounting and moving means moves said substrates through said coating station at a rate to effect the deposition of a monolayer of titanium and the oxidation of said monolayer to form titanium dioxide in substantially all rutile phase during a single pass of said substrates through said coating station.
